(19) United States
(12) Patent Application Publication
(10) Pub. No.: US 2012/0199891 A1
(43) Pub. Date: Aug. 9, 2012

(54) SEMICONDUCTOR DEVICE AND METHOD FOR MANUFACTURING SAME

(75) Inventors: Masahiko Suzuki, Osaka-shi (JP); Hirohiko Nishiki, Osaka-shi (JP); Yoshimasa Chikama, Osaka-shi (JP); Yoshifumi Ohta, Osaka-shi (JP); Tetsuya Aita, Osaka-shi (JP); Okifumi Nakagawa, Osaka-shi (JP); Takeshi Hara, Osaka-shi (JP)

(73) Assignee: SHARP KABUSHIKI KAISHA, Osaka-shi, Osaka (JP)

(21) Appl. No.: 13/499,960

(22) PCT Filed: Oct. 4, 2010
(86) PCT No.: PCT/JP2010/067379

§ 371 Date: Apr. 3, 2012

(30) Foreign Application Priority Data
Oct. 9, 2009 (JP) 2009-235644

(51) Int. Cl. H01L 29/78; H01L 21/336

(52) U.S. Cl. 257/288; 438/299; 257/E29.255; 257/E21.409

(57) ABSTRACT

A semiconductor device includes: a gate electrode (3) arranged on a substrate (1); a gate insulating layer (5) deposited over the gate electrode (3); an island of an oxide semiconductor layer (7) formed on the gate insulating layer (5) and including a channel region (7c) and first and second contact regions (7s, 7d) located on right- and left-hand sides of the channel region (7c); a source electrode (11) electrically connected to the first contact region (7s); a drain electrode (13) electrically connected to the second contact region (7d); and a protective layer (9) which is arranged on, and in contact with, the oxide semiconductor layer (7). The protective layer (9) covers the channel region (7c) on the surface of the oxide semiconductor layer (7), the sidewalls (7e) thereof located in a channel width direction with respect to the channel region (7c), and other portions (7f) thereof between the channel region (7c) and the sidewalls (7e). As a result, the hysteresis characteristic of a TFT that uses an oxide semiconductor can be improved and its reliability can be increased.

### TECHNICAL FIELD

The present invention relates to a semiconductor device including a thin-film transistor and a method for fabricating such a device.

### BACKGROUND ART

An active-matrix substrate for use in a liquid crystal display device and other devices includes switching elements such as thin-film transistors (which will be simply referred to herein as “TFTs”), each of which is provided for an associated one of pixels. As such switching elements, a TFT that uses an amorphous silicon film as its active layer (and will be referred to herein as an “amorphous silicon TFT”) and a TFT that uses a polysilicon film as its active layer (and will be referred to herein as a “polysilicon TFT”) have been used extensively.

In a polysilicon film, electrons and holes have higher mobility than in an amorphous silicon film. That is why a polysilicon TFT has a larger ON-state current, and can operate faster, than an amorphous silicon TFT. Consequently, if an active-matrix substrate is made using polysilicon TFTs, the polysilicon TFTs can be used not only as switching elements but also in a driver and other peripheral circuits as well. As a result, part or all of the driver and other peripheral circuits and the display section can be integrated together on the same substrate, which is advantageous. In addition, the pixel capacitor of a liquid crystal display device, for example, can be charged in a shorter switching time as well.

If a polysilicon TFT is to be fabricated, however, the process step of crystallizing an amorphous silicon film with a laser beam or heat, a thermal annealing process step, and other complicated process steps should be carried out, thus raising the manufacturing cost per unit area of the substrate. For that reason, polysilicon TFTs are currently used mostly in small- and middle-sized liquid crystal display devices.

Meanwhile, an amorphous silicon film can be formed more easily than a polysilicon film, and therefore, can be used more suitably to make a device with a huge area. That is why amorphous silicon TFTs are preferably used to make an active-matrix substrate that needs a big display area. In spite of their smaller ON-state current than polysilicon TFTs, amorphous silicon TFTs are currently used in the active-matrix substrate of most LCD TVs. Nevertheless, if amorphous silicon TFTs are used, the mobility of the amorphous silicon film is too low to enhance their performance unlimitedly. Generally speaking, a liquid crystal display device such as an LCD TV must realize not just a huge display screen but also much higher image quality and far lower power dissipation as well. For that reason, it should be difficult for an amorphous silicon TFT to meet all of these expectations fully. Also, recently, in order to make the frame area as narrow as possible and cut down the cost as much as one can, there have been increasing demands for further performance enhancement by either realizing driver-monolithic substrates or introducing a touchscreen panel function. However, it is difficult for an amorphous silicon TFT to meet these demands sufficiently.

Thus, to realize a TFT of even higher performance with the number of manufacturing processing steps and the manufacturing cost cut down, materials other than amorphous silicon and polysilicon have been tentatively used for the active layer of a TFT.

Patent Documents Nos. 1 and 2 propose making the active layer of a TFT of an oxide semiconductor film of zinc oxide, for example. Such a TFT will be referred to herein as an “oxide semiconductor TFT”. An oxide semiconductor has higher mobility than amorphous silicon. That is why an oxide semiconductor TFT can operate faster than an amorphous silicon TFT. On top of that, an oxide semiconductor film can be formed through a simpler process than a polysilicon film, and therefore, can be used to make a device that should have a huge display area.

If an oxide semiconductor film is used, however, oxygen vacancies would produce carrier electrons and might lower the resistance during the manufacturing process of the TFT (e.g., during a heat treatment process step). Also, if a TFT with a bottom gate structure is going to be fabricated, the underlying oxide semiconductor layer gets damaged easily in an etching process step to form source/drain electrodes or in the process step of forming an interlayer insulating film. For that reason, if an oxide semiconductor film is used as the active layer of the TFT, the TFT characteristic could have increased hysteresis or it could be difficult to realize stabilized TFT performance.

Thus, to overcome such a problem, Patent Documents Nos. 1 and 2 propose arranging an insulating film that functions as an etch stop (i.e., a channel protecting film) over the channel region of the active layer of an oxide semiconductor.

FIG. 15(a) is a plan view illustrating a conventional oxide semiconductor TFT that has such a channel protecting film. FIGS. 15(c) and 15(d) are cross-sectional views as respectively viewed on the planes and B-B′ shown in FIG. 15(a).

This oxide semiconductor TFT includes a substrate 1, a gate electrode 3 that is arranged on the substrate 1, a gate insulating layer 5 that covers the gate electrode 3, an oxide semiconductor layer 7 that has been formed on the gate insulating layer 5, a channel protecting film (which will be referred to herein as a “protective layer”) 99 that has been formed over the channel region of the oxide semiconductor layer 7, and source/drain electrodes 11 and 13 that are arranged on the oxide semiconductor layer 7. Each of the source/drain electrodes 11 and 13 is electrically connected to the oxide semiconductor layer 7. Patent Document No. 1 teaches using an amorphous oxide insulator as a material for the protective layer 99.

In the process of fabricating such an oxide semiconductor TFT as what is disclosed in Patent Document No. 1, when the source/drain electrodes 11 and 13 are formed by patterning, the channel region of the oxide semiconductor layer 7 is protected with the protective layer 99. As a result, damage that could be done on the channel region of the oxide semiconductor layer 7 should be minimized.

### CITATION LIST

### Patent Literature

Patent Document No. 1: Japanese Patent Application Laid-Open Publication No. 2008-166716
Patent Document No. 2: Japanese Patent Application Laid-Open Publication No. 2007-258675

### SUMMARY OF INVENTION

### Technical Problem

However, the present inventors discovered via experiments that even with a channel protecting film (or protective layer) 99 such as the one illustrated in FIG. 15 provided, sometimes the damage done on the oxide semiconductor layer 7 during the process could not be reduced sufficiently.

Specifically, according to Patent Document No. 1, even though the upper surface of the channel region of the oxide semiconductor layer 7 is in contact with the protective layer 99, the sidewall 8 of the oxide semiconductor layer 7 is not covered with the protective layer 99 but exposed as can be seen from FIG. 15(c). This is because when an oxide semiconductor film is patterned into islands of oxide semiconductor that form the oxide semiconductor layer 7, an insulating film to be the protective layer 99 is usually also patterned into the same shape.

That is why in a process step to be performed after the oxide semiconductor layer 7 has been formed, the exposed portion (e.g., the sidewall 8) of the oxide semiconductor layer 7 could be oxidized and reduced to produce oxygen vacancies there. Once such oxygen vacancies are produced, the oxide semiconductor layer 7 comes to have decreased resistance, thus possibly increasing the amount of leakage current to flow through the TFT and/or the hysteresis.

It is therefore an object of the present invention to reduce the hysteresis of such a TFT that uses an oxide semiconductor and stabilize the performance, and increase the reliability, of the TFT.

### Solution to Problem

A semiconductor device according to the present invention includes: a substrate; a gate electrode which is arranged on the substrate; a gate insulating layer which has been deposited over the gate electrode; an island of an oxide semiconductor layer which has been formed on the gate insulating layer and which includes a channel region and first and second contact regions that are located on right- and left-hand sides of the channel region; a source electrode which is electrically connected to the first contact region; a drain electrode which is electrically connected to the second contact region; and a protective layer which is arranged on, and in contact with, the oxide semiconductor layer. The protective layer covers the channel region on the surface of the oxide semiconductor layer, the sidewalls of the oxide semiconductor layer that are located in a channel width direction with respect to the channel region, and other portions of the oxide semiconductor layer between the channel region and the sidewalls.

In one preferred embodiment, the protective layer is arranged between the oxide semiconductor layer and the source and drain electrodes and has a first hole that connects the source electrode to the first contact region and a second hole that connects the drain electrode to the second contact region.

The first and second holes may partially overlap with the gate electrode.

In another preferred embodiment, the protective layer covers the upper surface and sidewalls of the surface of the oxide semiconductor layer entirely except the first and second contact regions.

When measured in a channel length direction, the width of the oxide semiconductor layer is preferably greater than that of the gate electrode.

At least the gate insulating layer and the oxide semiconductor layer are preferably interposed between the upper surface and sidewalls of the gate electrode and the source electrode and between the upper surface and sidewalls of the gate electrode and the drain electrode.

The protective layer may be further interposed between the upper surface and sidewalls of the gate electrode and the source electrode and between the upper surface and sidewalls of the gate electrode and the drain electrode.

A method for fabricating a semiconductor device according to the present invention includes the steps of: (A) forming a gate electrode on a substrate; (B) forming a gate insulating layer so that the gate insulating layer covers the upper surface and sidewalls of the gate electrode; (C) forming an island of an oxide semiconductor layer on the gate insulating layer; (D) forming a protective layer on the oxide semiconductor layer so that the protective layer covers the upper surface and sidewalls of the oxide semiconductor layer; (E) cutting first and second holes through the protective layer, thereby exposing two portions of the oxide semiconductor layer that are located on right- and left-hand sides of another portion thereof to be a channel region; and (F) forming a source electrode that is electrically connected to the oxide semiconductor layer through the first hole and a drain electrode that is electrically connected to the oxide semiconductor layer through the second hole.

### Advantageous Effects of Invention

According to the present invention, a decrease in the resistance of the oxide semiconductor layer of an oxide semiconductor TFT that will be caused when oxygen vacancies are produced in the oxide semiconductor layer can be minimized. As a result, the amount of leakage current to flow can be reduced and the hysteresis can be improved. Consequently, the intended TFT performance can be achieved with good stability and the reliability can be increased.

### BRIEF DESCRIPTION OF DRAWINGS

FIGS. 1(a) through 1(e) schematically illustrate a thin-film transistor as a first preferred embodiment of the present invention, wherein FIG. 1(a) is a plan view thereof, FIGS. 1(b) and 1(c) are cross-sectional views thereof as respectively viewed on the planes A-A′ and B-B′ shown in FIG. 1(a), and FIGS. 1(d) and 1(e) are respectively a plan view and a side view illustrating how respective regions of the oxide semiconductor layer are arranged in the thin-film transistor.

FIGS. 2(a) and 2(b) are cross-sectional views illustrating respective manufacturing process steps to fabricate a thin-film transistor as a semiconductor device according to the first preferred embodiment of the present invention.

FIGS. 3(a), 3(b) and 3(c) are respectively a plan view and cross-sectional views as viewed on the planes A-A′ and B-B′ illustrating the process step of forming a protective layer according to the first preferred embodiment.

FIGS. 4(a), 4(b) and 4(c) are respectively a plan view and cross-sectional views as viewed on the planes A-A′ and B-illustrating the process step of forming source and drain electrodes according to the first preferred embodiment.

FIGS. 5(a) and 5(b) are cross-sectional views illustrating the process step of forming a pixel electrode according to the first preferred embodiment.

FIGS. 6(a) through 6(d) schematically illustrate a thin-film transistor as a second preferred embodiment of the present invention, wherein FIG. 6(a) is a plan view thereof, FIGS. 6(b) and 6(c) are cross-sectional views thereof as respectively viewed on the planes A-A′ and B-B′ shown in FIG. 6(a), and FIG. 6(d) is a plan view illustrating how respective regions of the oxide semiconductor layer are arranged in the thin-film transistor.

FIGS. 7(a) through 7(c) schematically illustrate a thin-film transistor as a modified example of the second preferred embodiment of the present invention, wherein FIG. 7(a) is a plan view thereof, and FIGS. 7(b) and 7(c) are cross-sectional views thereof as respectively viewed on the planes A-A′ and B-B′ shown in FIG. 7(a).

FIG. 8 is a cross-sectional view illustrating a manufacturing processing step to fabricate a thin-film transistor as a semiconductor device according to the second preferred embodiment of the present invention.

FIGS. 9(a), 9(b) and 9(c) are respectively a plan view and cross-sectional views as viewed on the planes A-A′ and B-B′ illustrating the process step of forming a protective layer according to the second preferred embodiment.

FIGS. 10(a), 10(b) and 10(c) are respectively a plan view and cross-sectional views as viewed on the planes A-A′ and B-B′ illustrating the process step of forming source and drain electrodes according to the second preferred embodiment.

FIGS. 11(a) and 11(b) are cross-sectional views illustrating the process step of forming a pixel electrode according to the second preferred embodiment.

FIG. 12 is a graph showing the gate voltage-drain current (Vgs-Ids) characteristics of oxide semiconductor TFTs representing a specific example of the present invention and a comparative example.

FIG. 13 is a circuit diagram illustrating an active-matrix substrate according to a third specific preferred embodiment of the present invention.

FIG. 14 is a circuit diagram illustrating another active-matrix substrate according to the third preferred embodiment of the present invention.

FIGS. 15(a) through 15(c) schematically illustrate a conventional oxide semiconductor TFT, wherein FIG. 15(a) is a plan view thereof, and FIGS. 15(b) and 15(c) are cross-sectional views thereof as respectively viewed on the planes A-A′ and B-B′ shown in FIG. 15(a).

### DESCRIPTION OF EMBODIMENTS

### Embodiment 1

Hereinafter, a first specific preferred embodiment of a semiconductor device according to the present invention will be described with reference to the accompanying drawings. A semiconductor device as the first preferred embodiment of the present invention includes a thin-film transistor that has an active layer made of an oxide semiconductor (and that will be referred to herein as an “oxide semiconductor TFT”). The semiconductor device of this preferred embodiment needs to include at least one oxide semiconductor TFT and may be implemented broadly as a substrate, an active-matrix substrate, or any of various types of display devices and electronic devices that uses such a TFT.

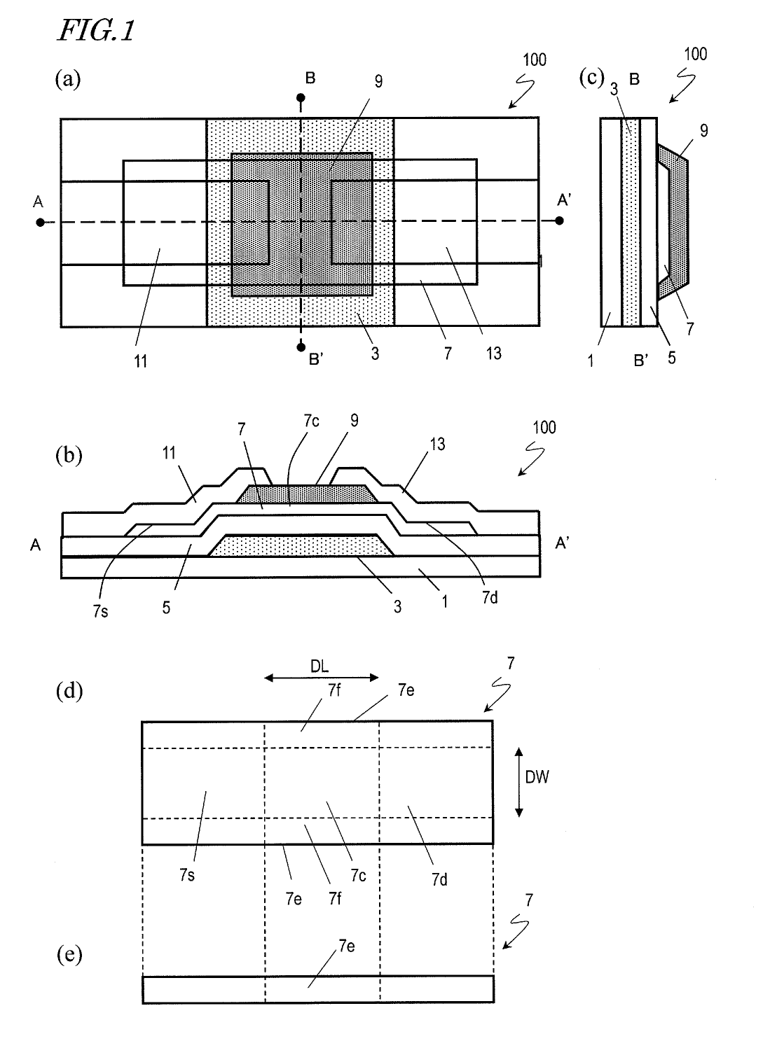

FIG. 1 schematically illustrates a thin-film transistor 100 as this first preferred embodiment of the present invention, wherein FIG. 1(a) is a plan view of the thin-film transistor 100, FIGS. 1(b) and 1(c) are cross-sectional views thereof as respectively viewed on the planes A-A′ and B-B′ shown in FIG. 1(a), and FIGS. 1(d) and 1(e) are respectively a plan view and a side view illustrating how respective regions of the oxide semiconductor layer are arranged in the thin-film transistor 100.

The thin-film transistor 100 includes a substrate 1, a gate electrode 3 that is arranged on the substrate 1, a gate insulating layer 5 that covers the gate electrode 3, an island of an oxide semiconductor layer 7 that has been formed on the gate insulating layer 5, a protective layer 9 that coats the oxide semiconductor layer 7, and source and drain electrodes 11 and 13 that are arranged on, and electrically connected to, the oxide semiconductor layer 7.

Each of the source and drain electrodes 11 and 13 contacts with the upper surface of the oxide semiconductor layer 7. As shown in FIGS. 1(d) and 1(e), regions 7s and 7d of the oxide semiconductor layer 7 that respectively contact with the source and drain electrodes 11 and 13 will be referred to herein as a “first contact region” and a “second contact region”, respectively. Another region 7c of the oxide semiconductor layer 7 that overlaps with the gate electrode 3 and that is located between the first and second contact regions 7s and 7d will be referred to herein as a “channel region”.

The protective layer 9 of this preferred embodiment covers the channel region 7c on the surface of the oxide semiconductor layer 7, its sidewalls 7e that are located in a channel width direction with respect to the channel region 7c, and other portions 7f thereof that connect the channel region 7c to the sidewalls 7e. In this description, within a plane that is parallel to the substrate 1, the direction DL that is parallel to a direction in which current flows through the channel region 7c will be referred to herein as a “channel length direction”, and the direction DW that intersects with the channel length direction at right angles will be referred to herein as a “channel width direction”.

According to this preferred embodiment, not only the channel region 7c of the oxide semiconductor layer 7 but also its sidewalls 7e that are located in the channel width direction with respect to the channel region 7c are covered with the protective layer 9. With such an arrangement adopted, in the manufacturing process to be described later, a patterning process step to form the source and drain electrodes 11 and 13 and other process steps can be performed with the channel region 7c, regions 7f and sidewalls 7e of the oxide semiconductor layer 7 covered with the protective layer 9. That is why it is possible to prevent oxygen vacancies from being produced due to an oxidation reduction reaction in and around the channel region 7c of the oxide semiconductor layer 7 during the manufacturing process. That is to say, since the decrease in the resistance of the oxide semiconductor layer 7 due to the oxygen vacancies can be minimized, the amount of leakage current to flow and the hysteresis can be reduced.

According to this preferred embodiment, as long as those regions 7c, 7e and 7f on the surface of the oxide semiconductor layer 7 are covered with the protective layer 9, the oxide semiconductor layer 7 and the protective layer 9 do not have to have the planar shapes shown in FIG. 1(a). It is preferred that the protective layer 9 be totally in contact with those regions 7c, 7e and 7f. It is also preferred that the protective layer 9 be longer in the channel width direction than the oxide semiconductor layer 7 and also contact with the upper surface of the gate insulating layer 5 that is located near the sidewalls 7e of the oxide semiconductor layer 7. As a result, the sidewalls 7e of the oxide semiconductor layer 7 can be protected more effectively with the protective layer 9.

In addition, this preferred embodiment has the following advantages, too.

Specifically, in the structure disclosed in Patent Document No. 2, the gate electrode, gate insulating film and oxide semiconductor layer are all patterned using the same mask, and the sidewalls of these layers are covered with an insulating film that functions as an etch stop layer. In such a structure, only that insulating film that functions as an etch stop layer is interposed between the sidewall of the gate electrode and the source electrode, and therefore, these electrodes could be short-circuited with each other. On the other hand, according to this preferred embodiment, since the gate insulating layer 5 and the oxide semiconductor layer 7 are longer than the gate electrode 3 in the channel length direction, the sidewall of the gate electrode 3 is covered with the gate insulating layer 5 and the oxide semiconductor layer 7. That is why at least these two layers, namely the gate insulating layer 5 and the oxide semiconductor layer 7, are interposed between the upper surface and sidewalls of the gate electrode 3 and the source electrode 11 and between the upper surface and sidewalls of the gate electrode 3 and the drain electrode 13. As a result, deterioration of the TFT performance due to the presence of oxygen vacancies in the oxide semiconductor layer 7 can be minimized with such a short-circuit avoided.

In this preferred embodiment, the oxide semiconductor layer 7 is preferably a layer of a Zn—O based semiconductor (which will be referred to herein as “ZnO”), an In—Ga—Zn—O based semiconductor (which will be referred to herein as “IGZO”), an In—Zn—O based semiconductor (which will be referred to herein as “IZO”), or a Zn—Ti—O based semiconductor (which will be referred to herein as “ZTO”).

Also, an oxide film of SiOx, for example, is preferably used as the protective layer 9. With an oxide film used, even if oxygen vacancies are produced in the oxide semiconductor layer 7, the oxygen vacancies can still be filled with oxygen included in the oxide film. As a result, the oxygen vacancies in the oxide semiconductor layer 7 can be reduced even more effectively.

It is preferred that the protective layer 9 have a thickness of 50 nm to 200 nm. The reason is as follows. Specifically, if the protective layer 9 has a thickness of 50 nm or more, the surface of the oxide semiconductor layer 7 can be protected even more effectively in the process step of forming source and drain electrodes by patterning. However, if the thickness were greater than 200 nm, then a big level difference would be made by the source/drain electrodes 11 and 13, and a disconnection and other defects could be caused.

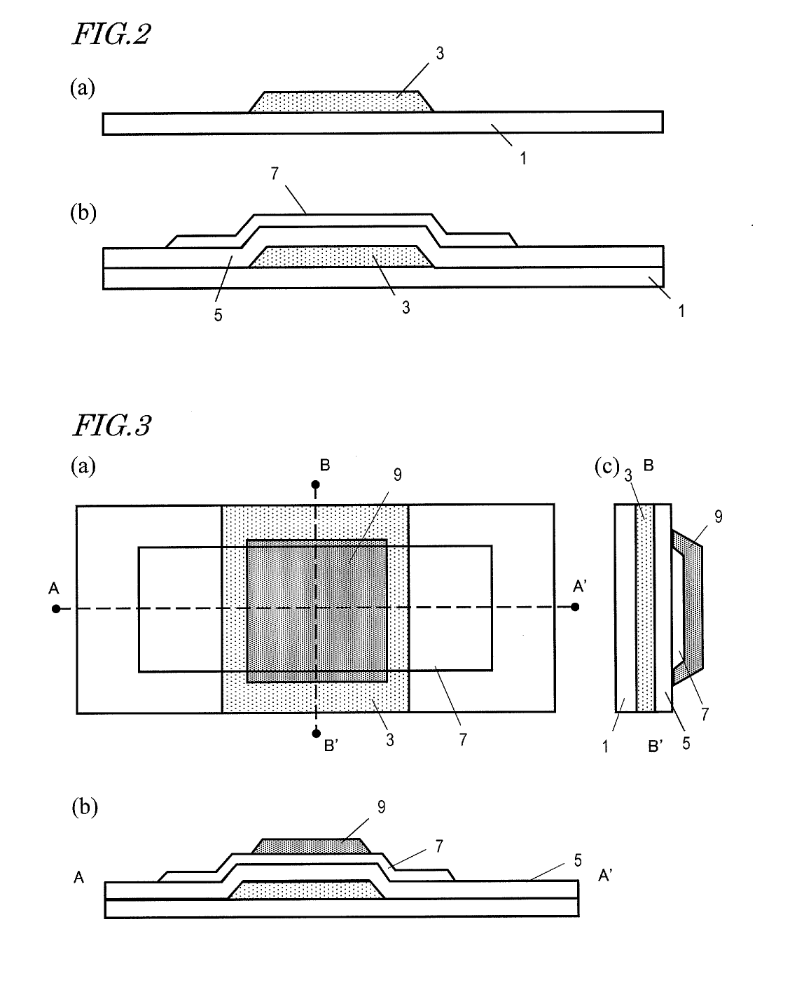

Hereinafter, it will be described with reference to the accompanying drawings how the thin-film transistor 100 may be fabricated. FIGS. 2 through 5 illustrate respective manufacturing process steps to be performed in order to fabricate the thin-film transistor 100.

First of all, as shown in FIG. 2(a), a gate electrode (which will also be referred to herein as a “gate line”) 3 is formed on a substrate 1 of glass, for example. The gate electrode 3 may be formed by depositing a conductor film on the substrate by sputtering or any other process and then by patterning the conductor film by photolithography. As the conductor film, a stack of Ti, Al and Ti films (with a thickness of 100 nm to 500 nm, for example) may be used.

Next, as shown in FIG. 2(b), a gate insulating layer 5 is deposited to cover the gate electrode 3 and then islands of an oxide semiconductor layer 7 is formed thereon. The gate insulating layer 5 may be formed by CVD process, for example, and may be an SiO₂ film with a thickness of 200 nm to 500 nm.

The oxide semiconductor layer 7 may be formed in the following manner. Specifically, first, an IGZO film is deposited to a thickness of 30 nm or 300 nm on the gate insulating layer 5 by sputtering process. Thereafter, a resist mask is defined by photolithography so as to cover a predetermined region of the IGZO film. Next, the exposed portion of the IGZO film, which is not covered with the resist mask, is removed by wet etching process. And then the resist mask is stripped, thereby obtaining islands of an oxide semiconductor layer 7. Optionally, the oxide semiconductor layer 7 may also be made of any other oxide semiconductor, instead of IGZO.

Next, a protective layer that protects a portion of the oxide semiconductor layer 7 to be a channel region is formed. FIGS. 3(a), 3(b) and 3(c) are respectively a plan view and cross-sectional views as viewed on the planes A-A′ and B-B′ illustrating the process step of forming the protective layer. As shown in FIGS. 3(a) to 3(c), the protective layer 9 is arranged so as to cover a region on the surface of the oxide semiconductor layer 7 to be a channel region and its sidewalls that are located in the channel width direction with respect to the former region. According to this preferred embodiment, first, an oxide film (e.g., an SiOx film) is deposited to a thickness of 50 nm to 200 nm on the gate insulating layer 5 and the oxide semiconductor layer 7 by CVD process. Next, a resist mask is defined by photolithography in order to cover a predetermined region of that oxide film. Subsequently, the exposed portion of the oxide film that is not covered with the resist mask is removed by dry etching. And then the resist mask is stripped, thereby obtaining the protective layer 9.

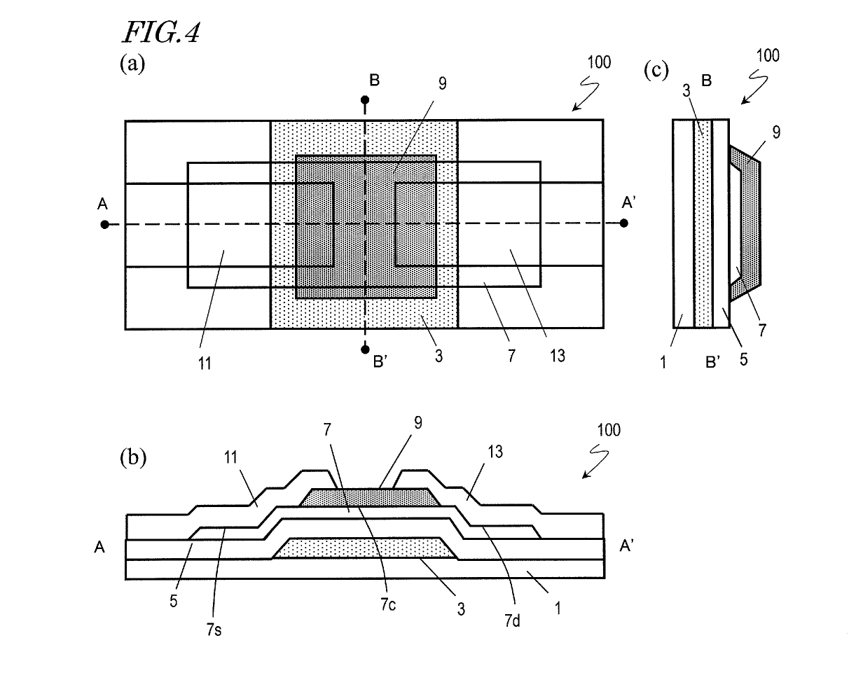

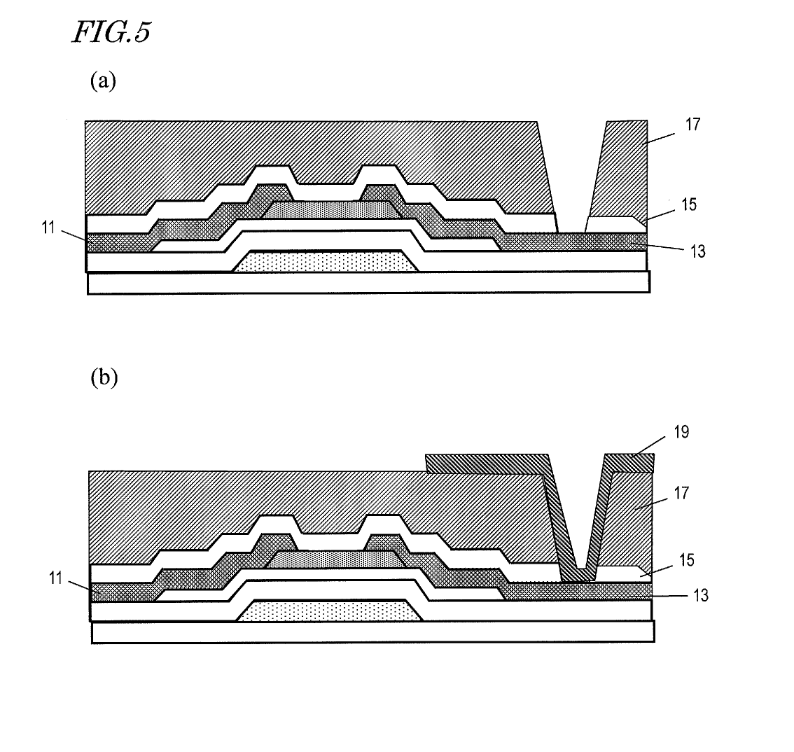

Subsequently, source and drain electrodes are formed. FIGS. 4(a), 4(b) and 4(c) are respectively a plan view and cross-sectional views as viewed on the planes A-A′ and B-B′ illustrating the process step of forming the source and drain electrodes. As shown in FIGS. 4(a) to 4(c), the source and drain electrodes 11 and 13 are arranged so as to contact with two regions of the oxide semiconductor layer 7 that are located on right- and left-hand sides of a region of the oxide semiconductor layer 7 to be a channel region. Of these two regions of the oxide semiconductor layer 7, one region that contacts with the source electrode 11 becomes a first contact region 7a and the other region that contacts with the drain electrode 13 becomes a second contact region 7d. These electrodes 11 and 13 can be formed by depositing a metal film by sputtering, for example, and then patterning the metal film. The metal film may be patterned by a known photolithographic process, for example. Specifically, a resist mask is defined on the metal film, the metal film is selectively etched away through the resist mask, and then the resist mask is stripped. In this manner, a thin-film transistor (as an oxide semiconductor TFT) 100 is completed.

The thin-film transistor 100 of this preferred embodiment may be used as a switching element on the active-matrix substrate of a liquid crystal display device, for example. And if the thin-film transistor 100 is used as a switching element, a pixel electrode that is electrically connected to the drain electrode 13 of the thin-film transistor 100 is formed in the following manner.

As shown in FIG. 5(a), a first interlayer insulating film (functioning as a protective coating) 15 and a second interlayer insulating film 17 are deposited in this order to cover the thin-film transistor 100. In this preferred embodiment, the first interlayer insulating film 15 is deposited by CVD process. The first interlayer insulating film 15 may be an SiO₂ film (with a thickness of 100 nm to 300 nm), for example. A hole that reaches the drain electrode 13 is cut through the SiO₂ film. Next, a layer of a photosensitive resin is deposited as the second interlayer insulating film 17. A hole is also cut through the second interlayer insulating film 17, thereby exposing the surface of the drain electrode 13.

Next, as shown in FIG. 5(b), a pixel electrode is formed in contact with the exposed surface of the drain electrode 13. In this preferred embodiment, a conductor film is deposited by sputtering process, for example, over the entire surface of the second interlayer insulating film 17 and inside the hole. As the conductor film, an ITO film (with a thickness of 50 nm to 200 nm) may be used. Next, the ITO film is patterned by photolithographic process, thereby obtaining the pixel electrode 19.

It should be noted that only one pixel electrode 19 and only one thin-film transistor 100 are illustrated in FIG. 5 for the sake of simplicity. Normally, however, the active-matrix substrate has a number of pixels, for each of which the pixel electrode 19 and the thin-film transistor 100 are provided.

According to the method described above, in the patterning process step to form the source and drain electrodes 11 and 13 and in the process step of depositing the first and second interlayer insulating films 15 and 17, not just a region of the oxide semiconductor layer 7 to be a channel region but also its sidewalls that are located in the channel width direction with respect to the former region are covered with the protective layer 9. That is why the damage to be done on the oxide semiconductor layer 7 during the manufacturing process can be reduced. As a result, the decrease in resistance to be caused by carriers that have been produced by oxygen vacancies in the oxide semiconductor layer can be minimized. Consequently, the amount of leakage current to flow through the thin-film transistor 100 and the hysteresis of the TFT performance can be both reduced. On top of that, if an oxide film is used as the protective layer 9, oxygen will be supplied from the oxide film to the oxide semiconductor layer 7. As a result, the oxygen vacancies to be produced in the oxide semiconductor layer 7 can be further reduced.

### Embodiment 2

Hereinafter, a second specific preferred embodiment of a semiconductor device according to the present invention will be described with reference to the accompanying drawings. In the semiconductor device of this preferred embodiment, the protective layer is formed so as to cover the oxide semiconductor layer entirely, which is a major difference from the thin-film transistor 100 that has already been described with reference to FIG. 1.

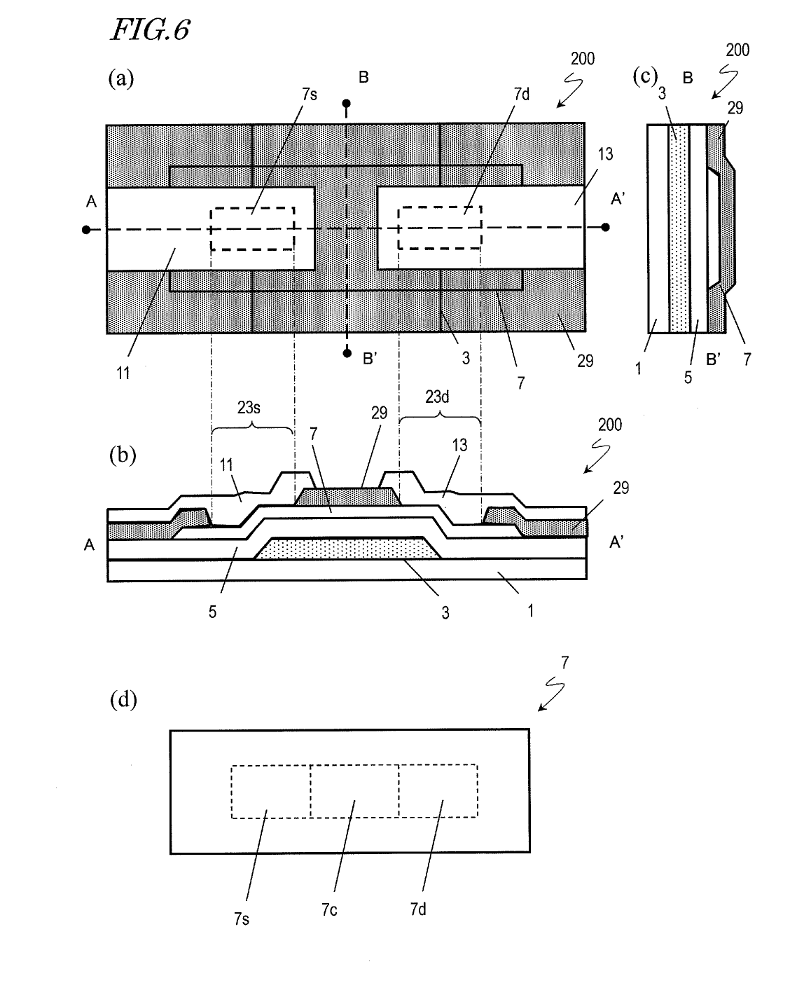

FIG. 6 schematically illustrates a thin-film transistor 200 as this second preferred embodiment of the present invention, wherein FIG. 6(a) is a plan view of the thin-film transistor 200, FIGS. 6(b) and 6(c) are cross-sectional views thereof as respectively viewed on the planes A-A′ and B-B′ shown in FIG. 6(a), and FIG. 6(d) is a plan view illustrating how respective regions of the oxide semiconductor layer are arranged in the thin-film transistor 200. In FIG. 6, any component also shown in FIG. 1 and having substantially the same function as its counterpart is identified by the same reference numeral and description thereof will be omitted herein.

In this thin-film transistor 200, a protective layer 29 is arranged so as to cover the upper surface and sidewalls of the island of oxide semiconductor layer 7. Although the protective layer 29 covers the entire surface of the substrate 1 in the example illustrated in FIG. 6, the protective layer 29 has only to cover the oxide semiconductor layer 7 completely and does not always have to cover the entire surface of the substrate 1.

The source and drain electrodes 11 and 13 are arranged on the protective layer 29, and are electrically connected to first and second contact regions 7s and 7d, respectively, in the oxide semiconductor layer 7 through holes 23s and 23d (which will be referred to herein as a “first hole” and a “second hole”, respectively, and) which have been cut through the protective layer 29.

According to this preferred embodiment, the entire upper surface of the oxide semiconductor layer 7 (except the first and second contact regions 7s and 7d) and the whole sidewalls thereof are covered with the protective layer 29. That is why in the patterning process step to form the source and drain electrodes 11 and 13, it is possible to prevent even more effectively oxygen vacancies from being produced in the oxide semiconductor layer 7. As a result, deterioration of the TFT performance to be caused by a decrease in the resistance of the oxide semiconductor layer 7 due to the presence of oxygen vacancies can be minimized. Specifically, the amount of leakage current to flow can be reduced and the TFT performance can be stabilized with the hysteresis reduced significantly.

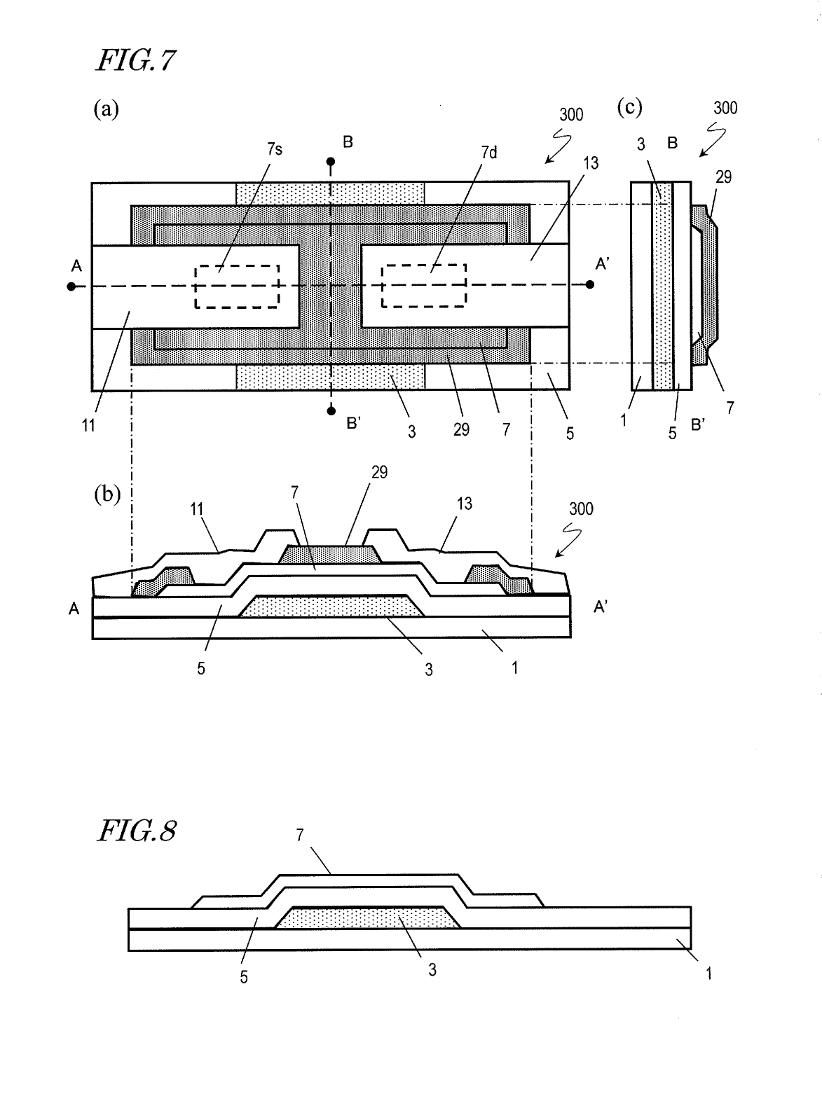

The protective layer 29 of this preferred embodiment does not have to cover the entire surface of the substrate 1. Alternatively, the protective layer 29 may also be patterned so as to be bigger by one size than the oxide semiconductor layer 7 as shown in FIG. 7. Even so, the protective layer 29 is also arranged so as to cover the entire upper surface of the oxide semiconductor layer 7 (except the first and second contact regions 7s and 7d) and the whole sidewalls thereof, and therefore, the same effect as what has already been described above can be achieved. It is preferred that the island of the protective layer 29 also contact with the upper surface of the gate insulating layer 5 that is located near the sidewalls of the oxide semiconductor layer 7. Then, the sidewalls of the oxide semiconductor layer can be protected even more securely with the protective layer 29.

In addition, according to this preferred embodiment, since the gate insulating layer 5 and the oxide semiconductor layer 7 are longer than the gate electrode 3 in the channel length direction, the sidewalls of the gate electrode 3 are covered with the gate insulating layer 5, the oxide semiconductor layer 7 and the protective layer 29. That is why at least these three layers, namely the gate insulating layer 5, the oxide semiconductor layer 7 and the protective layer 29, are interposed between the upper surface and sidewalls of the gate electrode 3 and the source electrode 11 and between the upper surface and sidewalls of the gate electrode 3 and the drain electrode 13. As a result, deterioration of the TFT performance due to the presence of oxygen vacancies in the oxide semiconductor layer 7 can be minimized with short-circuit between the gate electrode 3 and the source/drain electrodes 11 and 13 avoided.

Hereinafter, it will be described with reference to FIGS. 8 through 11 how the thin-film transistor 200 may be fabricated.

First of all, as shown in FIG. 8, a gate electrode (which will also be referred to herein as a “gate line”) 3, a gate insulating layer 5 and an island of an oxide semiconductor layer 7 are formed in this order on a substrate of glass, for example. The gate electrode 3, gate insulating layer 5 and oxide semiconductor layer 7 may be formed just as already described with reference to FIGS. 2(a) and 2(b). In this preferred embodiment, a stack of Ti, Al and Ti films (with a thickness of 100 nm to 500 nm, for example) is used as the gate electrode 3, an SiO₂ film (with a thickness of 200 nm to 500 nm) is deposited as the gate insulating layer 5, and an IGZO film (with a thickness of 30 nm to 300 nm) is deposited as the oxide semiconductor layer 7.

Next, a protective layer that covers the oxide semiconductor layer 7 is formed. FIGS. 9(a), 9(b) and 9(c) are respectively a plan view and cross-sectional views as viewed on the planes A-A′ and B-B′ illustrating the process step of forming the protective layer. As shown in FIGS. 9(a) to 9(c), the protective layer 29 is arranged so as to cover the entire oxide semiconductor layer 7. According to this preferred embodiment, the protective layer 29 covers the entire surface of the substrate 1 and contacts with the entire upper surface and sidewalls of the oxide semiconductor layer 7 and the upper surface of the gate insulating layer 5. Also, holes 23s and 23d are cut through the protective layer 29 so as to expose portions of the oxide semiconductor layer 7 that will be first and second contact regions, respectively. Those holes 23s and 23d should be located on the right- and left-hand sides of a region of the oxide semiconductor layer 7 that overlaps with the gate electrode 3 (i.e., a region to be a channel region). In this preferred embodiment, those holes 23s and 23d are arranged so as to partially overlap with the gate electrode 3.

The protective layer 29 may be formed by CVD process. In this preferred embodiment, an oxide film (e.g., an SiOx film) is deposited to a thickness of 50 nm to 200 nm. Next, the oxide film is patterned. Specifically, a resist mask is defined by photolithography in order to cover a predetermined region of that oxide film. Subsequently, the exposed portion of the oxide film that is not covered with the resist mask is removed by dry etching. And then the resist mask is stripped by washing, thereby cutting holes 23s and 23d through the oxide semiconductor layer 7.

If the island of protective layer 29 is formed as in the thin-film transistor 300 shown in FIG. 7, the island of protective layer 29 with the holes 23s and 23d may be obtained by patterning the oxide film as described above.

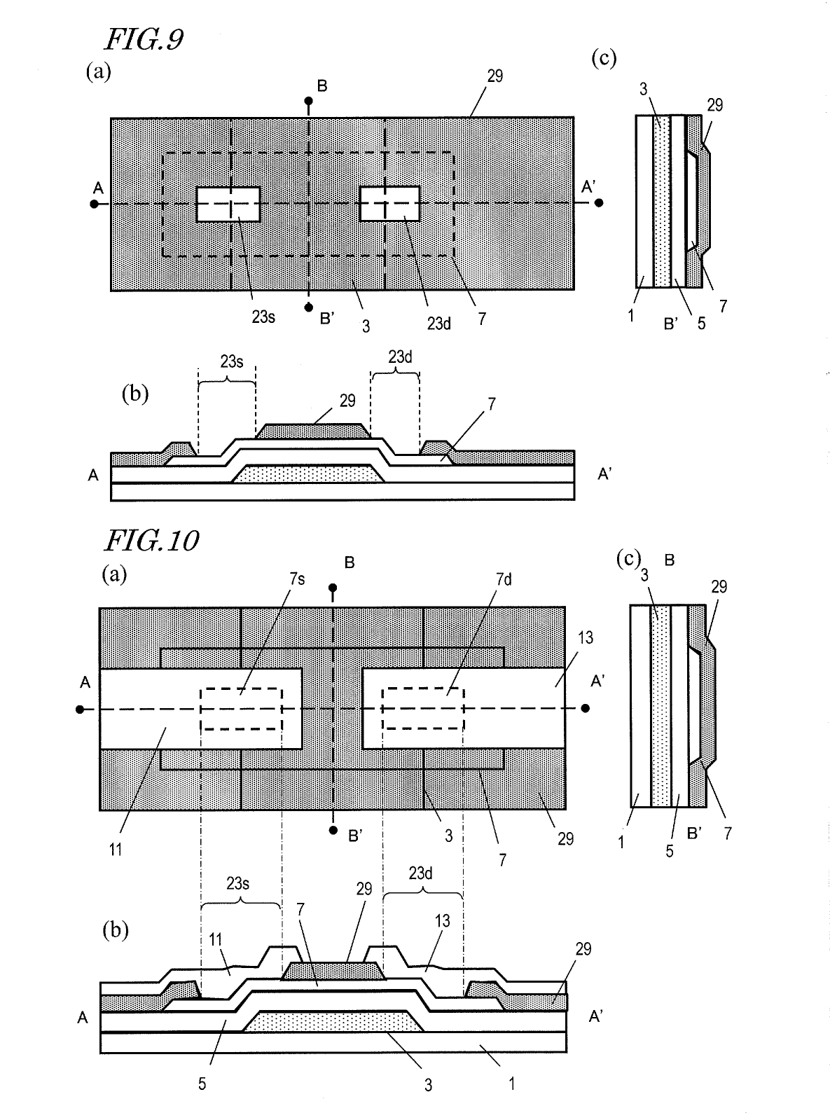

Subsequently, source and drain electrodes are formed. FIGS. 10(a), 10(b) and 10(c) are respectively a plan view and cross-sectional views as viewed on the planes and B-B′ illustrating the process step of forming the source and drain electrodes. As shown in FIGS. 10(a) to 10(c), the source and drain electrodes 11 and 13 are arranged so as to contact with two regions on the surface of the oxide semiconductor layer 7 that are exposed through the holes 23s and 23d. Of these two regions of the oxide semiconductor layer 7, one region that contacts with the source electrode 11 through the hole 23s becomes a first contact region 7s and the other region that contacts with the drain electrode 13 through the second hole 23d becomes a second contact region 7d. These electrodes 11 and 13 can be formed by depositing a metal film by sputtering, for example, and then patterning the metal film. The metal film may be patterned by a known photolithographic process, for example. Specifically, a resist mask is defined on the metal film, the metal film is selectively etched away through the resist mask, and then the resist mask is stripped. In this manner, a thin-film transistor (as an oxide semiconductor TFT) 200 is completed.

The thin-film transistor 200 of this preferred embodiment may be used on the active-matrix substrate of a liquid crystal display device, for example. And if the thin-film transistor 200 is used as a switching element, a pixel electrode that is electrically connected to the thin-film transistor 200 is formed in the following manner.

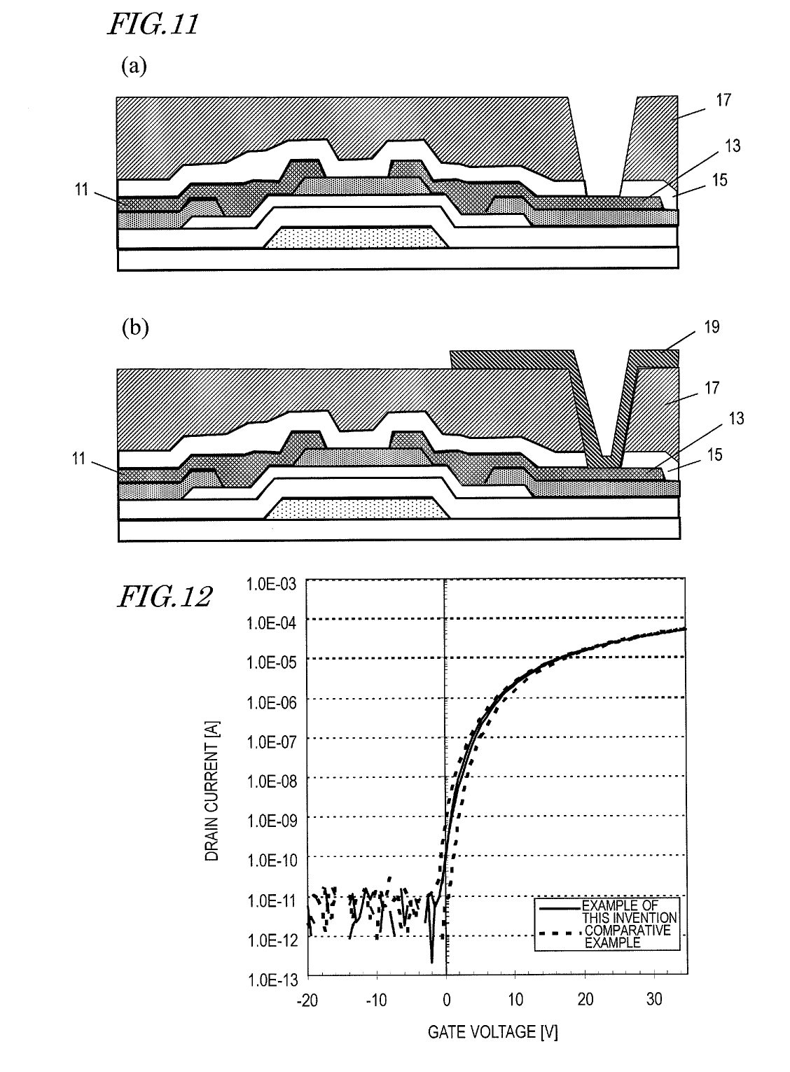

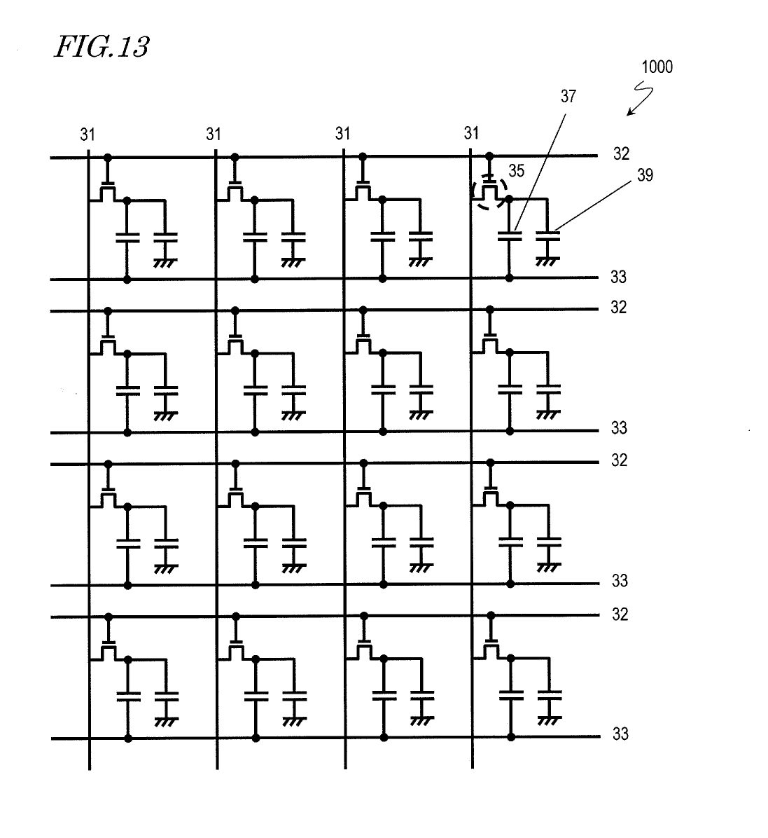

As shown in FIG. 11(a), a first interlayer insulating film (functioning as a protective coating) 15 and a second interlayer insulating film 17 are deposited in this order to cover the thin-film transistor 200. In this preferred embodiment, first, the first interlayer insulating film is deposited by CVD process. The first interlayer insulating film 15 may be an SiO₂ film (with a thickness of 100 nm to 300 nm), for example. A hole that reaches the drain electrode 13 is cut through the SiO₂ film. Next, a layer of a photosensitive resin is deposited as the second interlayer insulating film 17. A hole is also cut through the second interlayer insulating film 17, thereby exposing the surface of the drain electrode 13.

Next, as shown in FIG. 11(b), a pixel electrode is formed in contact with the exposed surface of the drain electrode 13. In this preferred embodiment, a conductor film is deposited by sputtering process, for example, over the entire surface of the second interlayer insulating film 17 and inside the hole. As the conductor film, an ITO film (with a thickness of 50 nm to 200 nm) may be used. Next, the ITO film is patterned by photolithographic process, thereby obtaining the pixel electrode 19.

It should be noted that only one pixel electrode 19 and only one thin-film transistor 100 are illustrated in FIG. 11 for the sake of simplicity. Normally, however, the active-matrix substrate has a number of pixels, for each of which the pixel electrode 19 and the thin-film transistor 200 are provided.

The materials for the oxide semiconductor layer 7 and protective layer 29 of this preferred embodiment are not particularly limited and may be the same as what is used in the first preferred embodiment described above.

In this preferred embodiment, each of the holes 23s and 23d of the protective layer 29 (i.e., each of the contact regions 7s and 7d) partially overlaps with the gate electrode 3. Optionally, the entire holes 23s and 23d may be located over the gate electrode 3. However, if the holes 23s and 23d only partially overlap with the gate electrode 3, the capacitance to be produced between the gate electrode 3 and the source/drain electrodes 11 and 13 that fill those holes 23s and 23d can be reduced compared to such a situation where the holes 23s and 23d are located right over the gate electrode 3.

It is also preferred that the holes 23s and 23d be cut so as to partially expose the upper surface of the oxide semiconductor layer 7 and that the sidewalls of the oxide semiconductor layer 7 be entirely covered with the protective layer 29. In that case, in the process step of forming interconnects after the protective layer 29 has been formed, the damage that could be done on the sidewalls of the oxide semiconductor layer 7 during the manufacturing process can be reduced effectively. Also, even if oxygen vacancies are produced in the oxide semiconductor layer 7, those oxygen vacancies can also be filled with oxygen that has been supplied from the protective layer 29 that covers the sidewalls of the oxide semiconductor layer 7.

### Examples and Comparative Examples

The present inventors tentatively made TFTs as specific examples of the present invention and comparative examples and measured their characteristics. Hereinafter, it will be described how we measured their characteristics and what results were obtained.

Specifically, as a TFT representing a specific example of the present invention, the present inventors made a TFT, of which the substrate 1 was covered entirely with the protective layer 29 (as shown in FIG. 6), by the same method as what has already been described with reference to FIGS. 8 through 11. Also, as a TFT representing a comparative example, the present inventors made a TFT having the structure shown in FIG. 15. In the TFT as a comparative example, the protective layer 99 was arranged only over the channel region of the oxide semiconductor layer 7 and the side surfaces 8 that were located in the channel width direction with respect to the channel region were not covered with the protective layer 99. Those two TFTs representing the specific example and comparative example had quite the same configuration (in terms of the materials and thicknesses of the respective layers, the size and so on) except the planar shape of the protective layer 29, 99.

Next, the present inventors measured the gate voltage-drain current (Vgs-Ids) characteristics of the two TFTs representing the specific example and the comparative example with the gate voltage increased and decreased. In making the measurements, Vgs was changed in the range of −20 V to 35 V and Vds was set to be 10 V.

The results of the measurements are shown in FIG. 12, of which the abscissa represents the potential Vgs at the gate electrode (i.e., the gate voltage) with respect to the potential at the drain electrode and the ordinate represents the drain current Ids. These results revealed that the TFT representing the specific example of the present invention had a smaller hysteresis (i.e., the magnitude of variation in threshold voltage with the history of the gate voltage) than the TFT representing the comparative example.

In the TFT representing the comparative example, oxygen vacancies are produced in a portion of the surface of the oxide semiconductor layer 7 that is not protected with the protective layer 99 (particularly the sidewalls 8 that are located in the channel width direction with respect to the channel region) during the manufacturing process of the TFT, thus causing a decrease in the resistance of the oxide semiconductor layer 7. As a result, the resistance in the channel region of the oxide semiconductor layer 7 cannot be controlled appropriately anymore with the voltage applied to the gate electrode 3. That is to say, the current flowing through the channel region (i.e., the drain current) cannot be controlled any longer. Consequently, the hysteresis increases.

On the other hand, in the TFT representing the specific example, the entire surface of the oxide semiconductor layer 7, including its sidewalls, is covered with the protective layer 29, and therefore, oxygen vacancies are much less likely to be produced in the oxide semiconductor layer 7 during the manufacturing process of the TFT. Consequently, the drain current can be controlled appropriately with the voltage applied to the gate electrode and the hysteresis can be reduced compared to the TFT representing the comparative example.

These results reveal that the hysteresis characteristic can be improved by covering not just the upper surface of the oxide semiconductor layer 7 but also its sidewalls with the protective layer 29. If the hysteresis characteristic improves (i.e., if the hysteresis can be reduced), an oxide semiconductor TFT with a higher degree of reliability can be obtained. In addition, as the contrast ratio can be increased and the flicker can be minimized on the display screen, the display quality can be improved as well.

### Embodiment 3

Hereinafter, a third specific preferred embodiment of a semiconductor device according to the present invention will be described. This third preferred embodiment is an active-matrix substrate that uses oxide semiconductor TFTs, which may be any of the thin-film transistors 100, 200 and 300 of the first and second preferred embodiments described above. The active-matrix substrate of this preferred embodiment may be used in various types of display devices including liquid crystal display devices, organic EL display devices, and inorganic EL display devices and numerous kinds of electronic devices that use any of those display devices.

FIG. 13 illustrates a circuit configuration for an active-matrix substrate 1000 for a liquid crystal display device. The active-matrix substrate 1000 includes, on an insulating substrate, a number of source lines 31, a number of gate lines 32 and a number of oxide semiconductor TFTs 35, each of which is arranged at the intersection between its associated pair of source and gate lines. The oxide semiconductor TFTs 35 may have either the structure shown in FIG. 6 or the structure shown in FIG. 1 or 7.

Each of the oxide semiconductor TFTs 35 has its source electrode connected to its associated source line 31, has its gate electrode connected to its associated gate line 32 and has its drain electrode connected to a pixel electrode (not shown). In the example illustrated in FIG. 13, storage capacitor lines (which are also called “Cs lines” or “common lines”) 33 are arranged parallel to the gate lines 32 and a storage capacitor (Cs) 37 is arranged between each oxide semiconductor TFT 35 and its associated common line 33. The storage capacitor 37 is connected in parallel to a liquid crystal layer (Clc) 39.

Although not shown, not only those oxide semiconductor TFTs 35 provided as switching elements (which will be referred to herein as “switching TFTs”) but also some or all of TFTs for drivers and other peripheral circuits (which will be referred to herein as “circuit TFTs”) may be integrated together on the same active-matrix substrate 1000 (to make a monolithic circuit). The peripheral circuits are arranged on an area (which is called a “frame area”) of the active-matrix substrate other than another area thereof including pixels (which is called a “display area”). The oxide semiconductor TFTs of the present invention use an oxide semiconductor layer that has high mobility (of 10 cm²/Vs or more, for example) as their active layer, and therefore, can be used as not only pixel TFTs but also circuit TFTs as well in such a situation.

The semiconductor device of this preferred embodiment may be the active-matrix substrate of an organic EL display device. On the active-matrix substrate of an organic EL display device, light-emitting elements are generally arranged on a pixel-by-pixel basis, and each light-emitting element includes an organic EL layer, a switching TFT and a driving TFT.

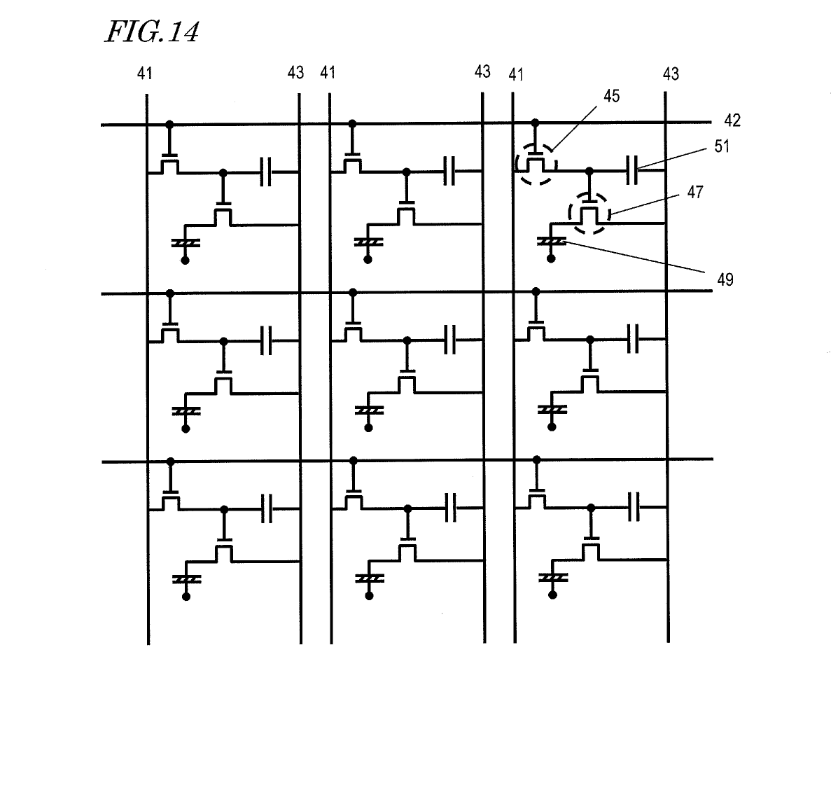

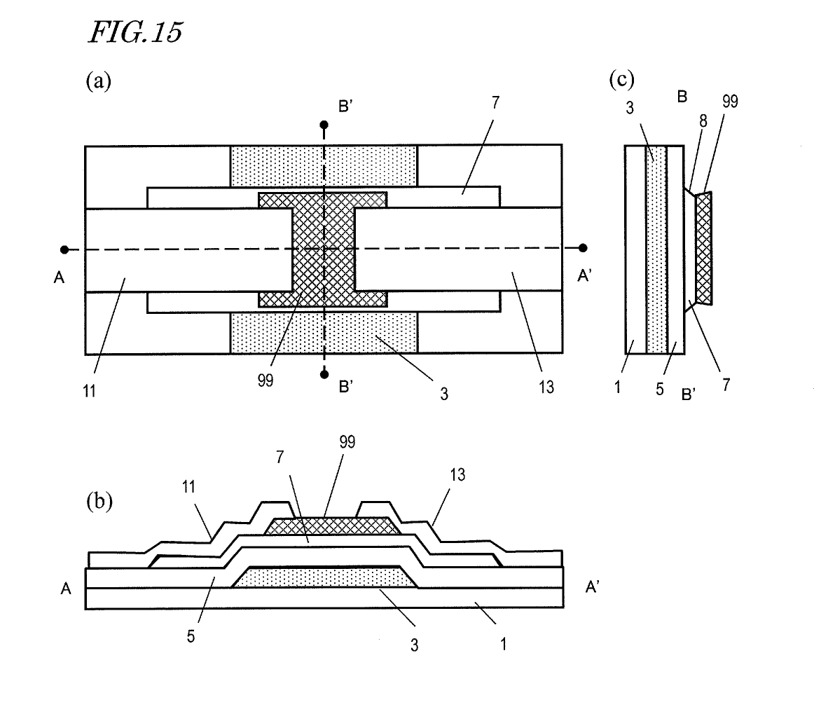

FIG. 14 illustrates a circuit configuration for an active-matrix substrate for an organic EL display device. The active-matrix substrate includes, on an insulating substrate, a number of source lines 41, a number of gate lines 42 and a number of power lines 43 that run parallel to the source lines 41. In each region (i.e., a pixel) surrounded with these lines 41, 42 and 43, arranged are a switching TFT 45 that is located at the intersection between its associated source line 41 and gate line 42, an organic EL layer 49 and a driving TFT 47 that is located between its associated power line 43 and the organic EL layer 49. The switching TFTs 45 and the driving TFTs 47 may be either oxide semiconductor TFTs with the structure shown in FIG. 6 or oxide semiconductor TFTs with the structure shown in FIG. 1 or 7.

Each of those switching TFTs 45 has its source electrode connected to its associated source line 41, its gate electrode connected to its associated gate line 42, and its drain electrode connected to the gate electrode of its associated driving TFT 47 and its associated power line 43 by way of a storage capacitor 51. Meanwhile, each driving TFT 47 has its source electrode connected to its associated power line 43 and its drain electrode connected to the organic EL layer 49.

In the preferred embodiment described above, the present invention is supposed to be applied to the active-matrix substrate of a liquid crystal display device or an organic EL display device. However, the present invention is naturally applicable to the active-matrix substrate of an inorganic EL display device as well.

### INDUSTRIAL APPLICABILITY

The present invention is applicable broadly to various types of devices that use a thin-film transistor. Examples of such devices include circuit boards such as an active-matrix substrate, display devices such as a liquid crystal display, an organic electroluminescence (EL) display, and an inorganic electroluminescence display, image capture devices such as an image sensor, and electronic devices such as an image input device and a fingerprint scanner. The present invention can be used particularly effectively in a liquid crystal display with a big monitor screen.

### REFERENCE SIGNS LIST

1 substrate
3 gate electrode
5 gate insulating layer
7 oxide semiconductor layer (active layer)
7s first contact region
   7d second contact region
   7c channel region
   7e sidewalls of oxide semiconductor layer that are located in channel width direction with respect to channel region
7f regions on the surface of oxide semiconductor layer that connect channel region to sidewalls
9, 29 protective layer
11 source electrode
13 drain electrode
15, 17 interlayer insulating film
19 pixel electrode
23s, 23d holes of protective layer
100, 200, 300 thin-film transistor
1000 active-matrix substrate

1. A semiconductor device comprising:
a substrate;
a gate electrode which is arranged on the substrate;
a gate insulating layer which has been deposited over the gate electrode;
an island of an oxide semiconductor layer which has been formed on the gate insulating layer and which includes a channel region and first and second contact regions that are located on right- and left-hand sides of the channel region;
a source electrode which is electrically connected to the first contact region;
a drain electrode which is electrically connected to the second contact region; and
a protective layer which is arranged on, and in contact with, the oxide semiconductor layer,
wherein the protective layer is a single layer and in contact with the channel region on the surface of the oxide semiconductor layer, the sidewalls of the oxide semiconductor layer that are located in a channel width direction with respect to the channel region, and other portions of the oxide semiconductor layer between the channel region and the sidewalls.

2. The semiconductor device of claim 1, wherein the protective layer is arranged between the oxide semiconductor layer and the source and drain electrodes and has a first hole that connects the source electrode to the first contact region and a second hole that connects the drain electrode to the second contact region.

3. The semiconductor device of claim 2, wherein the first and second holes partially overlap with the gate electrode.

4. The semiconductor device of claim 2, wherein the protective layer covers the upper surface and sidewalls of the surface of the oxide semiconductor layer entirely except the first and second contact regions.

5. The semiconductor device of claim 1, wherein when measured in a channel length direction, the width of the oxide semiconductor layer is greater than the width of the gate electrode.

6. The semiconductor device of claim 1, wherein at least the gate insulating layer and the oxide semiconductor layer are interposed between the upper surface and sidewalls of the gate electrode and the source electrode and between the upper surface and sidewalls of the gate electrode and the drain electrode.

7. The semiconductor device of claim 6, wherein the protective layer is further interposed between the upper surface and sidewalls of the gate electrode and the source electrode and between the upper surface and sidewalls of the gate electrode and the drain electrode.

8. A method for fabricating a semiconductor device, the method comprising the steps of:
(A) forming a gate electrode on a substrate;
(B) forming a gate insulating layer so that the gate insulating layer covers the upper surface and sidewalls of the gate electrode;
(C) forming an island of an oxide semiconductor layer on the gate insulating layer;
(D) forming a protective layer on the oxide semiconductor layer so that the protective layer is in contact with the upper surface and sidewalls of the oxide semiconductor layer, the protective layer being a single layer;
(E) cutting first and second holes through the protective layer, thereby exposing two portions of the oxide semiconductor layer that are located on right- and left-hand sides of another portion thereof to be a channel region; and
(F) forming a source electrode that is electrically connected to the oxide semiconductor layer through the first hole and a drain electrode that is electrically connected to the oxide semiconductor layer through the second hole.

9. The semiconductor device of claim 1, wherein the protective layer has a thickness of 50 nm to 200 nm.

10. The semiconductor device of claim 1, wherein the sidewalls of the oxide semiconductor layer that are located in a channel length direction with respect to the channel region are in contact with the source electrode or the drain electrode.
